(19) United States
(12) Patent Application Publication
(10) Pub. No.: US 2026/0150374 A1
(43) Pub. Date: May 28, 2026

(54) TRANSISTOR DEVICE WITH MULTI-THICKNESS GATE DIELECTRIC

(71) Applicant: Taiwan Semiconductor Manufacturing Company, Ltd., Hsinchu (TW)

(72) Inventors: Yi-Huan Chen, Hsinchu City (TW); Jhu-Min Song, Nantou City (TW); Chia-Jui Lee, Hsinchu County (TW); Fei-Yun Chen, Hsinchu (TW); Chen-Liang Chu, Hsin-Chu City (TW)

(21) Appl. No.: 18/956,160

(22) Filed: Nov. 22, 2024

(51) Int. Cl. H01L 29/423; H01L 29/66

(52) U.S. Cl. CPC H10D 64/516; H10D 64/017; H10D 64/519

(57) ABSTRACT

An integrated chip including a first source/drain region and a second source/drain region along a semiconductor substrate. A channel region extends along the substrate from the first source/drain region to the second source/drain region. The gate electrode is between the first and second source/drain regions. The gate electrode has first and second outer sidewalls and a bottom surface extending from the first outer sidewall to the second outer sidewall. The gate dielectric layer is between the gate electrode and the channel region. A lateral portion of the gate dielectric layer extends laterally along the bottom surface of the gate electrode. First and second vertical portions of the gate dielectric layer extend upward from the lateral portion along the first and second outer sidewalls of the gate electrode.

### BACKGROUND

Modern day integrated chips (ICs) comprise millions or billions of semiconductor devices formed on a semiconductor substrate (e.g., silicon). Integrated chips may use many different types of semiconductor devices, depending on an application of an IC. For example, many integrated chips include low voltage transistor devices, medium voltage transistor devices, and/or high voltage transistor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip including a transistor along a semiconductor substrate.

FIG. 2 illustrates a top view of some embodiments of the integrated chip of FIG. 1.

FIG. 3 and FIG. 4 illustrate cross-sectional views of some embodiments of the integrated chip of FIG. 2.

FIG. 5 illustrates a top view of some other embodiments of the integrated chip of FIG. 1.

FIG. 6 illustrates a cross-sectional view of some embodiments of the integrated chip of FIG. 5.

FIG. 7 illustrates a cross-sectional view of some embodiments of the integrated chip of FIG. 1 in which a plurality of well regions are in the semiconductor substrate.

FIG. 8 and FIG. 9 illustrate top views of some embodiments of the integrated chip of FIG. 7.

FIG. 10 and FIG. 11 illustrate cross-sectional views of some embodiments of the integrated chip of FIG. 7 in which a gate electrode of the transistor includes a plurality of metal layers.

FIG. 12 illustrates a top view of some embodiments of the integrated chip of FIG. 10 and FIG. 11.

FIG. 13 and FIG. 14 illustrate cross-sectional views of some embodiments of the integrated chip of FIG. 10 in which the gate electrode includes a plurality of base metal layers and a plurality of work function metal layers.

FIGS. 15-17 illustrate top views of some embodiments of the integrated chip of FIG. 13 and FIG. 14.

FIG. 18 illustrates a cross-sectional view of some embodiments of the integrated chip of FIGS. 16 and 17.

FIGS. 19-21 illustrate top views of some other embodiments of the gate electrode and the gate dielectric layer of the transistor.

FIGS. 22-25 illustrate cross-sectional views of some other embodiments of the integrated chip of FIG. 18.

FIGS. 26-37 illustrate cross-sectional views of some embodiments of a method for forming an integrated chip including a transistor along a semiconductor substrate.

FIG. 38 illustrates a flow diagram of some embodiments of a method for forming an integrated chip including a transistor along a semiconductor substrate.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip includes a transistor along a semiconductor substrate. The transistor includes a pair of source/drain regions along the semiconductor substrate. A channel region extends along the semiconductor substrate between the source/drain regions. A gate electrode is over the channel region and between the source/drain regions. A gate dielectric layer is between the gate electrode and the channel region.

In some cases, the thickness of the gate dielectric layer is reduced to improve performance of the transistor, reduce short channel effects (SCE), and reduce transistor mismatch across the integrated chip (e.g., reduce performance variation between alike transistors on the integrated chip). However, in some cases, reducing the thickness of the gate dielectric layer can reduce the reliability of the gate dielectric layer. For example, reducing the thickness of the gate dielectric layer can reduce the integrity of the gate dielectric layer (e.g., make the gate dielectric layer more susceptible to breakdown).

Conversely, in some cases, the thickness of the gate dielectric layer is increased to increase the reliability of the gate dielectric layer. However, in some cases, increasing the thickness of the gate dielectric layer can reduce the performance of the transistor, increase SCE, and increase transistor mismatch.

In various embodiments of the present disclosure, the gate dielectric layer has a reduced thickness along a center of the channel region and an increased thickness along opposite ends of the channel region to improve the balance between the performance of the transistor and the reliability of the transistor. For example, a lateral portion of the gate dielectric layer extends laterally along a bottom surface of the gate electrode. The lateral portion has a reduced thickness to improve the performance of the transistor. Further, a first vertical portion of the gate dielectric layer extends upward from the lateral portion along the first outer sidewall of the gate electrode and a second vertical portion of the gate dielectric layer extends upward from the lateral portion along the second outer sidewall of the gate electrode. The vertical portions have increased thickness to improve the reliability of the transistor. By reducing the thickness of the gate dielectric layer directly under the gate electrode and increasing the thickness of the gate dielectric layer along the sidewalls of the gate electrode, the balance between the performance of the transistor and the reliability of the transistor can be improved and transistor mismatch can be reduced.

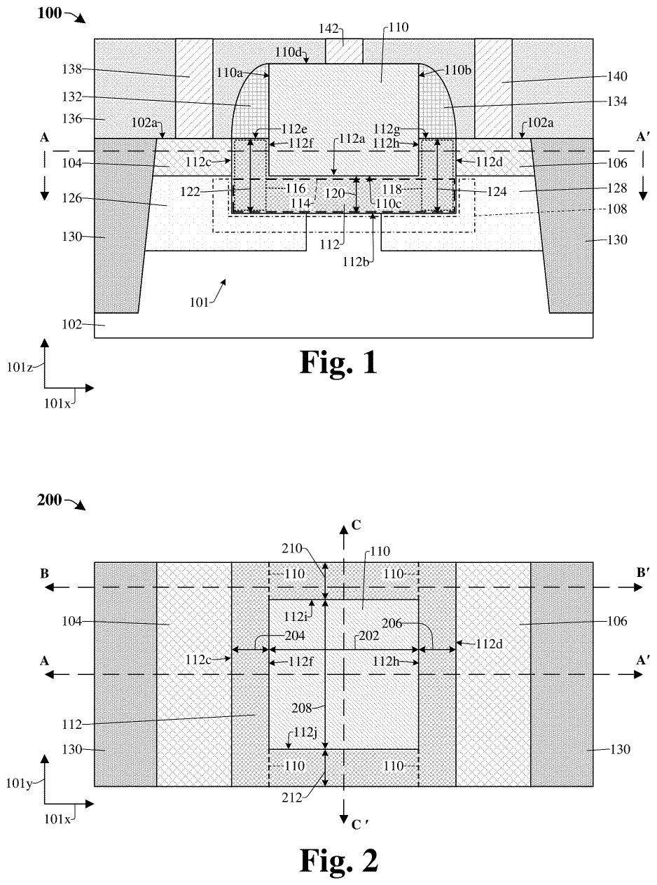

FIG. 1 illustrates a cross-sectional view 100 of some embodiments of an integrated chip including a transistor 101 along a semiconductor substrate 102. FIG. 1 is illustrated in an x-z plane formed by axis 101x and axis 101z.

The transistor 101 includes a first source/drain region 104 and a second source/drain region 106 arranged along a semiconductor substrate 102. A channel region 108 extends along the semiconductor substrate 102 from the first source/drain region 104 to the second source/drain region 106. Source/drain region(s) may refer to a source or a drain, individually or collectively dependent upon the context.

The transistor 101 includes a gate electrode 110 over the channel region 108 and between the first source/drain region 104 and the second source/drain region 106. The gate electrode 110 has a first outer sidewall 110a, a second outer sidewall 110b, a bottom surface 110c extending from a bottom of the first outer sidewall 110a to a bottom of the second outer sidewall 110b, and a top surface 110d extending from a top of the first outer sidewall 110a to a top of the second outer sidewall 110b.

The transistor 101 includes a gate dielectric layer 112 between the gate electrode 110 and the channel region 108. A lateral portion 114 of the gate dielectric layer 112 extends laterally along the bottom surface 110c of the gate electrode 110. A first vertical portion 116 of the gate dielectric layer 112 extends upward from the lateral portion 114 along the first outer sidewall 110a of the gate electrode 110. A second vertical portion 118 of the gate dielectric layer 112 extends upward from the lateral portion 114 along the second outer sidewall 110b of the gate electrode 110.

The lateral portion 114 is delimited by a first upper surface 112a, a bottom surface 112b, a first outer sidewall 112c, and a second outer sidewall 112d of the gate dielectric layer 112. The first vertical portion 116 is delimited by a second upper surface 112e, the bottom surface 112b, the first outer sidewall 112c, and a first inner sidewall 112f of the gate dielectric layer 112. The second vertical portion 118 is delimited by a third upper surface 112g, the bottom surface 112b, the second outer sidewall 112d, and a second inner sidewall 112h of the gate dielectric layer 112.

The lateral portion 114 has a first thickness 120 (e.g., the distance between upper surface 112a and bottom surface 112b as measured along axis 101z). The first vertical portion 116 has a second thickness 122 (e.g., the distance between upper surface 112e and bottom surface 112b as measured along axis 101z). The second vertical portion 118 has a third thickness 124 (e.g., the distance between upper surface 112g and bottom surface 112b as measured along axis 101z). The second thickness 122 and the third thickness 124 are greater than the first thickness 120.

By reducing thickness 120 of the gate dielectric layer 112 along the lateral portion 114 (e.g., directly under the center of the gate electrode 110), the performance of the transistor 101 can be improved and short channel effects (SCE) can be reduced. Further, by increasing thicknesses 122, 124 of the gate dielectric layer 112 along the vertical portions 116, 118 (e.g., along edges of the gate electrode 110), the reliability of the transistor 101 can be improved (e.g., the integrity of the gate dielectric layer 112 can be improved). By improving the performance and the reliability of the transistor 101, mismatch between the transistor 101 and other alike transistors (not shown) on the integrated chip can be reduced.

In some embodiments, thickness 120 ranges from 50 angstroms to 300 angstroms, 100 angstroms to 250 angstroms, or some other suitable range. In some embodiments, thickness 122 and thickness 124 range from 70 angstroms to 400 angstroms, 150 angstroms to 350 angstroms, or some other suitable range.

A first lightly doped source/drain region 126 is under the first source/drain region 104 in the semiconductor substrate 102 and a second lightly doped source/drain region 128 is under the second source/drain region 106 in the semiconductor substrate 102. In some embodiments, the first lightly doped source/drain region 126 and the second lightly doped source/drain region 128 extend under the gate dielectric layer 112 and under the gate electrode 110.

A shallow trench isolation (STI) structure 130 surrounds a portion of the semiconductor substrate 102 including the first source/drain region 104, the second source/drain region 106, the channel region 108, the first lightly doped source/drain region 126, and the second lightly doped source/drain region 128. In some embodiments, the STI structure 130 delimits an active device area of the semiconductor substrate 102.

A first sidewall spacer 132 extends along the first outer sidewall 110a of the gate electrode 110 and a second sidewall spacer 134 extends along the second outer sidewall 110b of the gate electrode 110. The first sidewall spacer 132 is over the first vertical portion 116 of the gate dielectric layer 112 and the second sidewall spacer 134 is over the second vertical portion 118 of the gate dielectric layer 112.

A dielectric structure 136 is over the semiconductor substrate 102 and the gate electrode 110. The dielectric structure 136 comprises one or more dielectric layers (e.g., interlayer dielectric layers, intermetal dielectric layers, etch stop layers, dielectric liner layers, etc.). A first contact 138 extends through the dielectric structure 136 to the first source/drain region 104. A second contact 140 extends through the dielectric structure 136 to the second source/drain region 106. A third contact 142 extends through the dielectric structure 136 to the gate electrode 110.

In some embodiments, the gate electrode 110 is below a top surface 102a of the semiconductor substrate 102, above the top surface 102a of the semiconductor substrate 102, and directly between the first source/drain region 104 and the second source/drain region 106. In some such embodiments, the gate dielectric layer 112 is below the top surface 102a of the semiconductor substrate 102. For example, the first outer sidewall 112c of the gate dielectric layer 112 extends along a first sidewall (not labeled) of the semiconductor substrate 102 from upper surface 112e to bottom surface 112b, the second outer sidewall 112d of the gate dielectric layer 112 extends along a second sidewall (not labeled) of the semiconductor substrate 102 from upper surface 112g to bottom surface 112b, and the bottom surface 112b of the gate dielectric layer 112 extends along an upper surface (not labeled) of the semiconductor substrate 102 from sidewall 112c to sidewall 112d. In such embodiments, a horizontal line (e.g., line A-A′) intersects the source/drain regions 104, 106, sidewalls 110a, 110b of the gate electrode 110, and sidewalls 112c, 112f, 112h, 112d of the gate dielectric layer 112. In some embodiments, a top of the gate dielectric layer 112 (e.g., upper surface 112e and upper surface 112g) is approximately coplanar with the top surface 102a of the semiconductor substrate 102.

In some embodiments, the semiconductor substrate 102 comprises silicon or some other suitable semiconductor. In some embodiments, the semiconductor substrate 102 has a first doping type (e.g., p-type) and source/drain regions 104, 106, 126, 128 have a second doping type different than the first doping type (e.g., n-type). In some embodiments, the gate electrode 110 comprises aluminum, tungsten, hafnium, zirconium, titanium, tantalum, ruthenium, palladium, platinum, cobalt, nickel, or some other suitable conductive material. In some embodiments, the gate dielectric layer 112 comprises silicon oxide, hafnium oxide, aluminum oxide, or some other suitable dielectric material. In some embodiments, the STI structure 130 comprises silicon oxide, silicon nitride, or some other suitable material. In some embodiments, sidewall spacers 132, 134 comprise silicon oxide, silicon nitride, or some other suitable material. In some embodiments, the dielectric layers of the dielectric structure 136 comprise silicon oxide, silicon nitride, silicon carbide, silicon oxynitride, or some other suitable material. In some embodiments, contacts 138, 140, 142 comprise tungsten, aluminum, or some other suitable material.

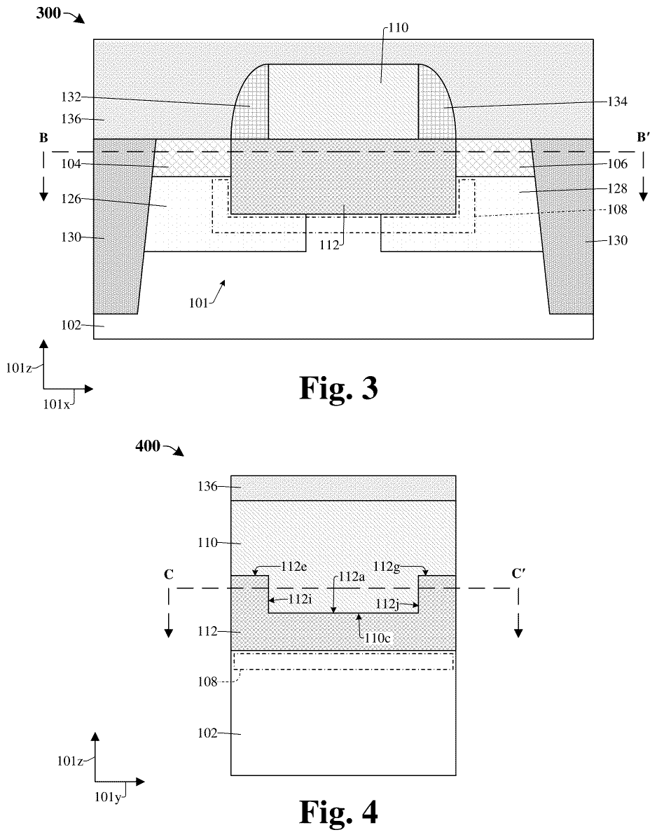

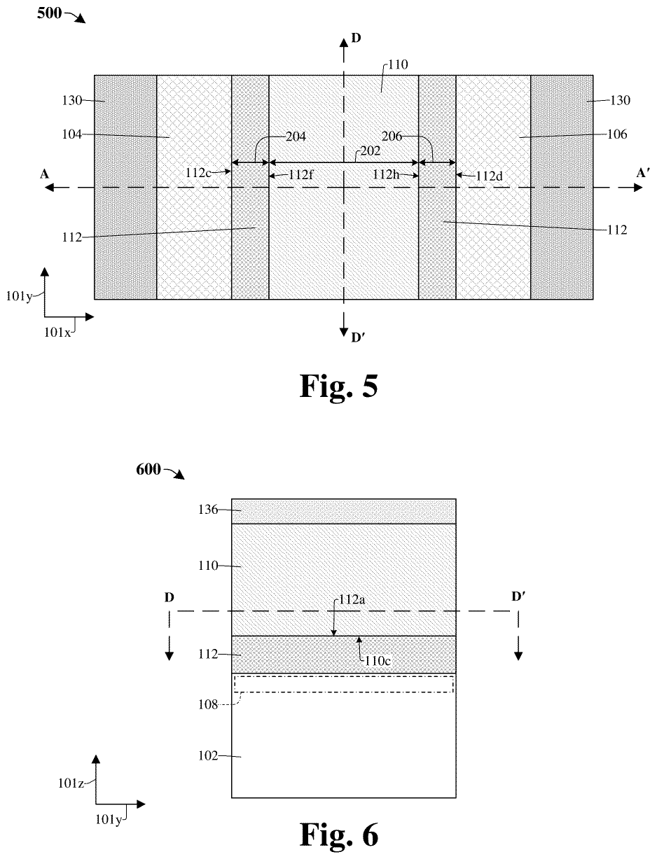

FIG. 2 illustrates a top view 200 of some embodiments of the integrated chip of FIG. 1. FIG. 3 illustrates a cross-sectional view 300 and FIG. 4 illustrates a cross-sectional view 400 of some embodiments of the integrated chip of FIG. 2. In some embodiments, top view 200 of FIG. 2 is taken across line A-A′ of FIG. 1. In some embodiments, line B-B′ of cross-sectional view 300 corresponds to line B-B′ of top view 200, and line C-C′ of cross-sectional view 400 corresponds to line C-C′ of top view 200. FIG. 2 is illustrated in an x-y plane formed by axis 101x and axis 101y. FIG. 3 is illustrated in an x-z plane formed by axis 101x and axis 101z. FIG. 4 is illustrated in a y-z plane formed by axis 101y and axis 101z.

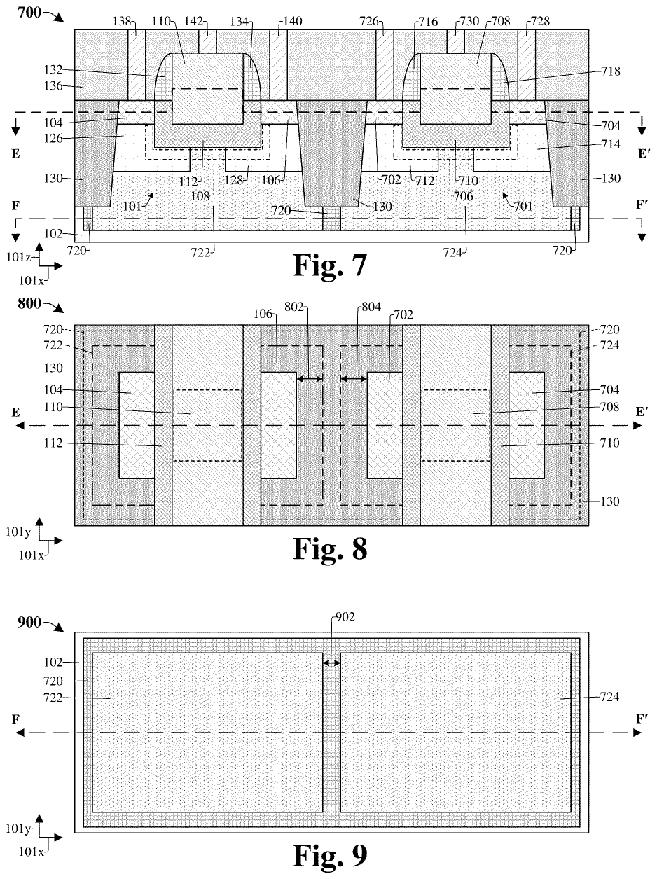

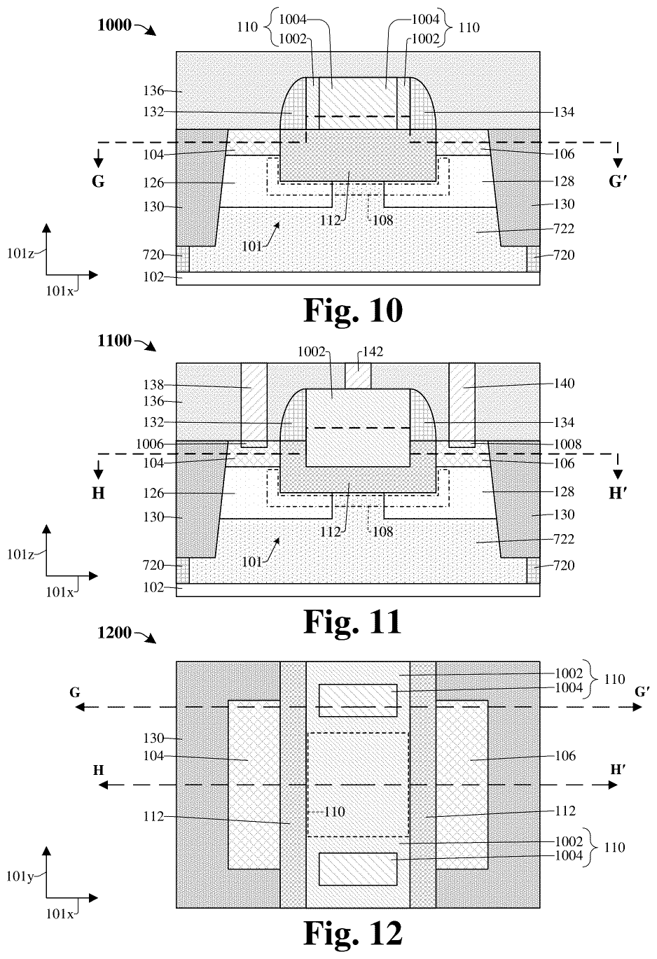

FIG. 5 illustrates a top view 500 of some other embodiments of the integrated chip of FIG. 1. FIG. 6 illustrates a cross-sectional view 600 of some embodiments of the integrated chip of FIG. 5. In some embodiments, top view 500 of FIG. 5 is taken across line A-A′ of FIG. 1. In some embodiments, line D-D′ of cross-sectional view 600 corresponds to line D-D′ of top view 500. FIG. 5 is illustrated in an x-y plane formed by axis 101x and axis 101y. FIG. 6 is illustrated in a y-z plane formed by axis 101y and axis 101z.

Referring to FIGS. 2-6, the gate electrode 110 and the gate dielectric layer 112 are elongated along axis 101y. In some embodiments (e.g., in the embodiments illustrated in FIGS. 2-4), the gate dielectric layer 112 (e.g., vertical portions of the gate dielectric layer 112) laterally surrounds a portion of the gate electrode 110 in a closed path. For example, the gate electrode 110 is directly between sidewalls 112f, 112h of the gate dielectric layer 112 and directly between sidewalls 112i, 112j of the gate dielectric layer. In some such embodiments, upper surface 112e and upper surface 112g are one continuous surface that laterally surrounds the gate electrode 110 in a closed path. In some other embodiments (e.g., in the embodiments illustrated in FIGS. 5-6), the gate dielectric layer 112 is on opposite sides of the gate electrode 110 but does not surround the gate electrode 110 in a closed path. In some such embodiments, upper surface 112e and upper surface 112g are separate surfaces that are spaced apart on opposite sides of the gate electrode 110.

In some embodiments, the distance 202 between sidewall 112f and sidewall 112h of the gate dielectric layer 112 (e.g., as measured along axis 101x) ranges from 0.1 micrometers to 10 micrometers, from 0.2 micrometers to 8 micrometers, or some other suitable distance. In some embodiments, the distance 204 between sidewall 112c and sidewall 112f of the gate dielectric layer 112, and the distance 206 between sidewall 112d and sidewall 112h of the gate dielectric layer 112 (e.g., as measured along axis 101x) range from 0.01 micrometers to 5 micrometers, from 0.05 micrometers to 5 micrometers, or some other suitable distance.

In some embodiments (e.g., FIG. 2), the distance 208 between sidewall 112i and sidewall 112j of the gate dielectric layer 112 (e.g., as measured along axis 101y) ranges from 0.1 micrometers to 10 micrometers, from 0.2 micrometers to 8 micrometers, or some other suitable distance. In some embodiments, the distance 210 between sidewall 112i of the gate dielectric layer 112 and a first edge of the active area of the transistor 101, and the distance 212 between sidewall 112j of the gate dielectric layer 112 and a second edge of the active area of the transistor 101 (e.g., as measured along axis 101y) range from 0.01 micrometers to 5 micrometers, from 0.05 micrometers to 5 micrometers, or some other suitable distance.

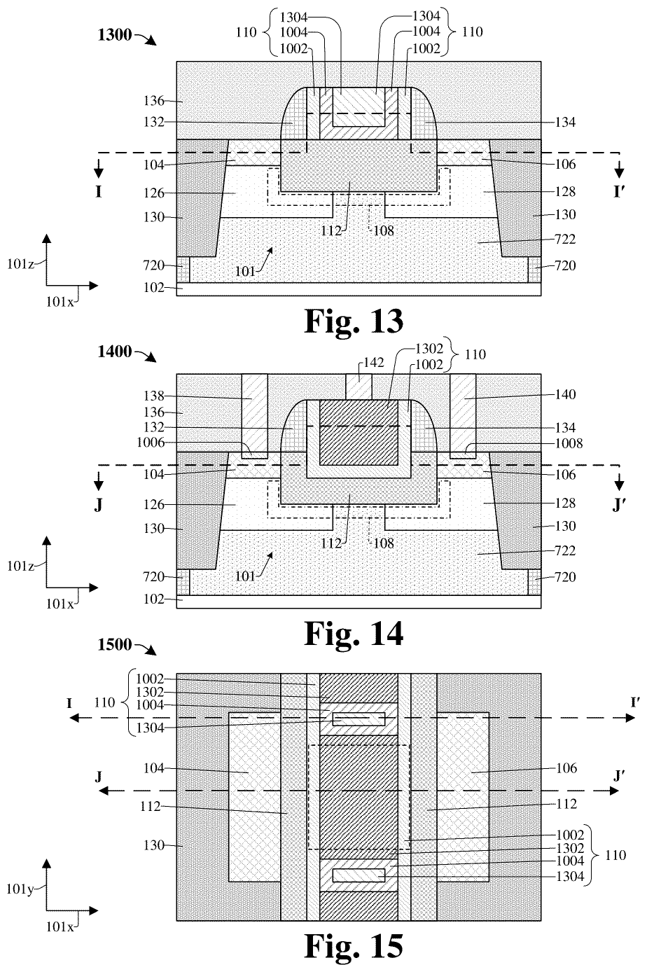

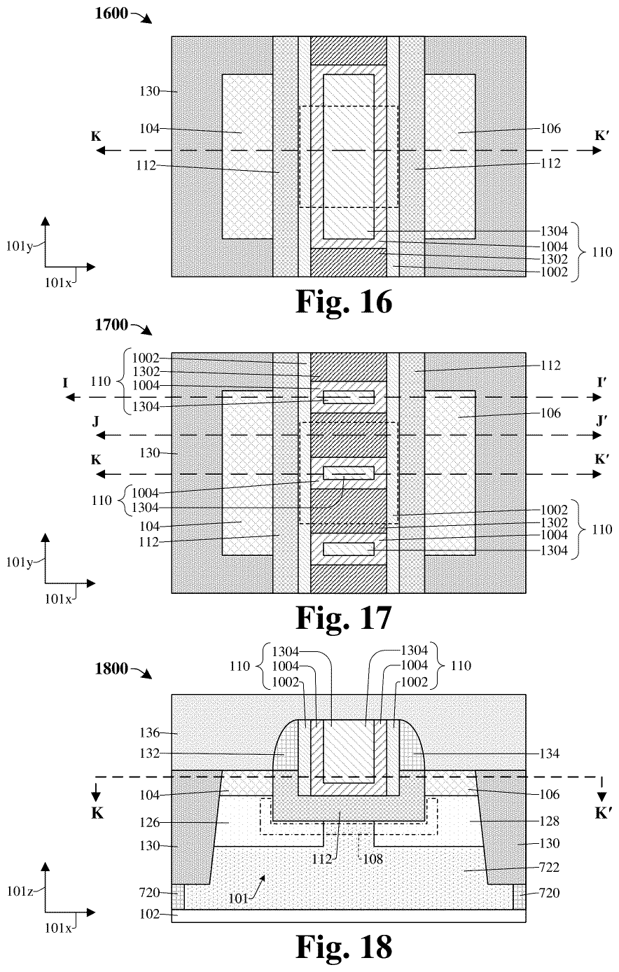

FIG. 7 illustrates a cross-sectional view 700 of some embodiments of the integrated chip of FIG. 1 in which a plurality of well regions are in the semiconductor substrate 102. FIG. 8 illustrates a top view 800 of some embodiments of the integrated chip of FIG. 7. FIG. 9 illustrates a top view 900 of some embodiments of the integrated chip of FIG. 7. In some embodiments, top view 800 of FIG. 8 is taken across line E-E′ of FIG. 7. In some embodiments, top view 900 of FIG. 9 is taken across line F-F′ of FIG. 7.

The integrated chip includes transistor 101 and a second transistor 701 laterally spaced from transistor 101. Transistor 701 includes a first source/drain region 702, a second source/drain region 704, a channel region 706, a gate electrode 708, a gate dielectric layer 710, a first lightly doped source/drain region 712, a second lightly doped source/drain region 714, a first sidewall spacer 716, a second sidewall spacer 718. A first contact 726 extends through the dielectric structure 136 to the source/drain region 704. A second contact 728 extends through the dielectric structure 136 to source/drain region 706. A third contact 730 extends through the dielectric structure 136 to gate electrode 708. In some embodiments, the STI structure 130 surrounds transistor 101 and transistor 701 and extends directly between the transistor 101 and transistor 701 to isolate transistor 101 from transistor 701.

A heavily doped well region 720 is in the semiconductor substrate 102. In some embodiments, the heavily doped well region 102 has a first doping type. A first lightly doped well region 722 is in the heavily doped well region 720. A second lightly doped well region 724 is in the heavily doped well region 720 and laterally spaced from the first lightly doped well region 722. The heavily doped well region 720 surrounds the first lightly doped well region 722 and the second lightly doped well region 724 and extends directly between the first lightly doped well region 722 and the second lightly doped well region 724. The first lightly doped well region 722 and the second lightly doped well region 724 have the first doping type. The source/drain regions 104, 106, 126, 128 have a second doping type, different than the first doping type. The semiconductor substrate 102 has the first doping type or the second doping type. The doping concentration of the heavily doped well region 720 is greater than the doping concentration of the first lightly doped well region 722 and greater than the doping concentration of the second lightly doped well region 724. In some embodiments, the STI structure 130 extends surrounds the first lightly doped well region 722 and the second lightly doped well region 724 and extends directly between the first lightly doped well region 722 and the second lightly doped well region 724.

Transistor 101 is disposed along the first lightly doped well region 722 and transistor 701 is disposed along the second lightly doped well region 724. For example, source/drain regions 104, 106 (and lightly doped source/drain regions 126, 128) and channel region 108 are in the first lightly doped well region 722, and source/drain regions 702, 704 (and lightly doped source/drain regions 712, 714) and channel region 706 are in the second lightly doped well region 724.

By including the lightly doped well regions 722, 724, the doping concentration along the channel regions 108, 706 can be reduced. Further, reducing the doping concentration along the channel regions 108, 706 can reduce short channel effects at the transistors 101, 701. Furthermore, reducing short channel effects can reduce mismatch between the transistors 101, 701.

In some embodiments, distance 902 between the first lightly doped well region 722 and the second lightly doped well region ranges from 0.1 to 0.9 micrometers, from 0.2 to 0.8 micrometers, or some other suitable range. In some embodiments, distance 802 between the perimeter of the source/drain regions of the first transistor (e.g., source/drain region 106) and the perimeter of the first lightly doped well region 722 ranges from 0.1 to 0.9 micrometers, from 0.2 to 0.8 micrometers, or some other suitable range. In some embodiments, distance 804 between the perimeter of the source/drain regions of transistor 701 (e.g., source/drain region 702) and the perimeter of the second lightly doped well region 724 ranges from 0.1 to 0.9 micrometers, from 0.2 to 0.8 micrometers, or some other suitable range. In some embodiments, distances 902, 802, 804 can be adjusted to tune the threshold voltages of the transistors 101, 701 and to reduce mismatch between the transistors 101, 701.

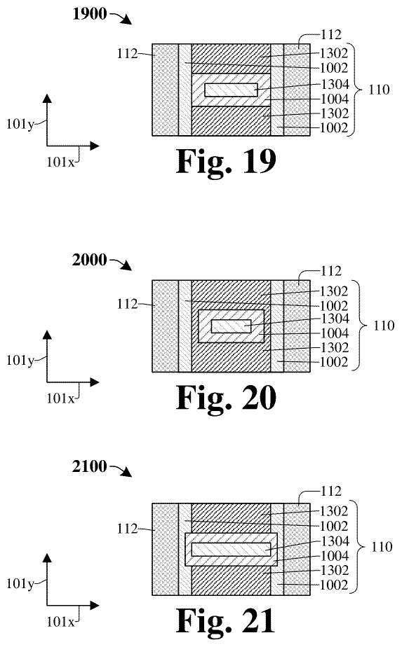

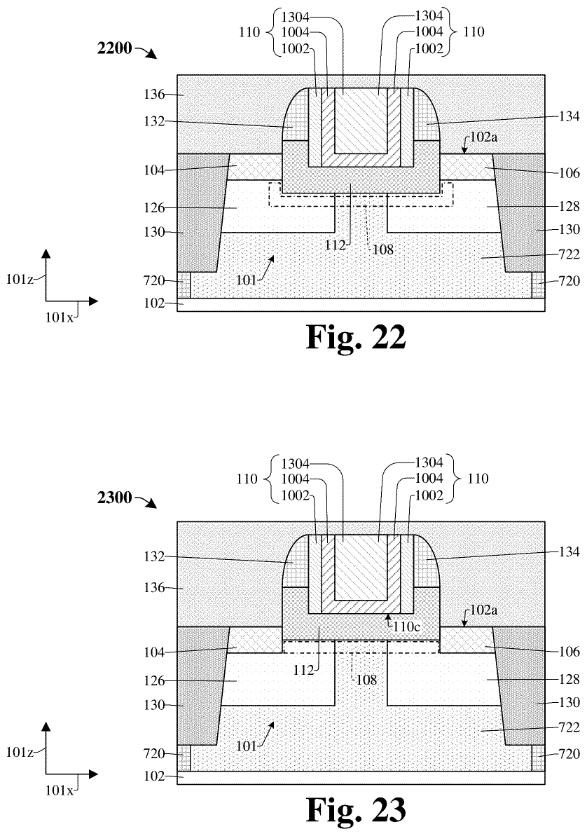

FIG. 10 illustrates a cross-sectional view 1000 and FIG. 11 illustrates cross-section view 1100 of some embodiments of the integrated chip of FIG. 7 in which the gate electrode 110 includes a plurality of metal layers. FIG. 12 illustrates a top view 1200 of some embodiments of the integrated chip of FIG. 10 and FIG. 11. In some embodiments, top view 1200 of FIG. 12 is taken across line G-G′ of FIG. 10 and line H-H′ of FIG. 11.

The gate electrode 110 includes a first base metal layer 1002 and a first work function metal layer 1004. The first base metal layer 1002 laterally surrounds the first work function metal layer 1004 along sidewalls of the first work function metal layer 1004. The first base metal layer 1002 comprises a first metal. The first work function metal layer 1004 comprises a second metal different than the first metal. The first work function metal layer 1004 (e.g., the second metal) has a work function of a first “type” and the source/drain regions 104, 106 have work functions of a second “type” different than the first “type”. For example, in embodiments where the transistor 101 is an n-channel transistor (e.g., an NMOS), the first source/drain region 104 and the second source/drain region 106 are n-type source/drain regions (e.g., source/drain regions having n-type work functions and n-type doping), and the first work function metal layer 1004 comprises a p-type work function metal (e.g., a work function metal having a p-type work function). In embodiments where the transistor 101 is a p-channel transistor (e.g., an PMOS), the first source/drain region 104 and the second source/drain region 106 are p-type source/drain regions (e.g., source/drain regions having p-type work functions and p-type doping), and the first work function metal layer 1004 comprises an n-type work function metal (e.g., a work function metal having an n-type work function). In some embodiments, an n-type work function is a work function that is within about 3.5 to 4.5 eV, less than about 4.5 eV, less than about 4.3 eV, less than about 4.1 eV, or some other suitable value. In some embodiments, a-p-type work function is a work function that is within about 4.5 to 5.5 eV, greater than about 4.5 eV, greater than about 4.7 eV, greater than about 4.9 eV, or some other suitable value.

By including the first work function metal layer 1004 (having a work function type that is different than that of the source/drain regions 104, 106) in the gate electrode 110, the threshold voltage of the transistor 101 can be increased and/or tuned (e.g., to counteract decreases in the threshold voltage caused by short channel effects or the like). Increasing the threshold voltage of the transistor 101 can reduce mismatch between the transistor 101 and other transistors on the integrated chip.

In some embodiments, a p-type work function metal is a material that comprises a metal and that has a work function that is within about 4.5 to 5.5 eV, greater than about 4.5 eV, greater than about 4.7 eV, greater than about 4.9 eV, or some other suitable value. In some embodiments, p-type work function metals include, for example, titanium nitride, tantalum nitride, tungsten carbon nitride, platinum, palladium, nickel, a combination of the foregoing, or some other suitable material.

In some embodiments, an n-type work function metal is a material that comprises a metal and that has a work function that is within about 3.5 to 4.5 eV, less than about 4.5 eV, less than about 4.3 eV, less than about 4.1 eV, or some other suitable value. In some embodiments, n-type work function metals include, for example, titanium, titanium aluminide, titanium aluminum carbide, tantalum, tantalum aluminide, tantalum aluminum carbide, zirconium, hafnium, a combination of the foregoing, or some other suitable material.

In some embodiments, the integrated chip includes silicide layers 1006, 1008 between contacts 138, 140 and source/drain regions 104, 106 where contacts 138, 140 the contact source/drain regions 104, 106, respectively.

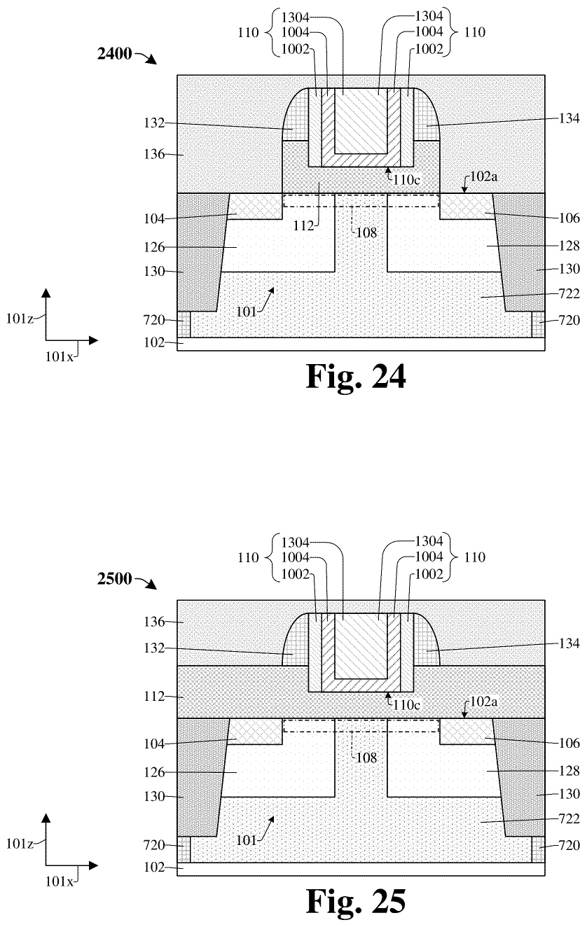

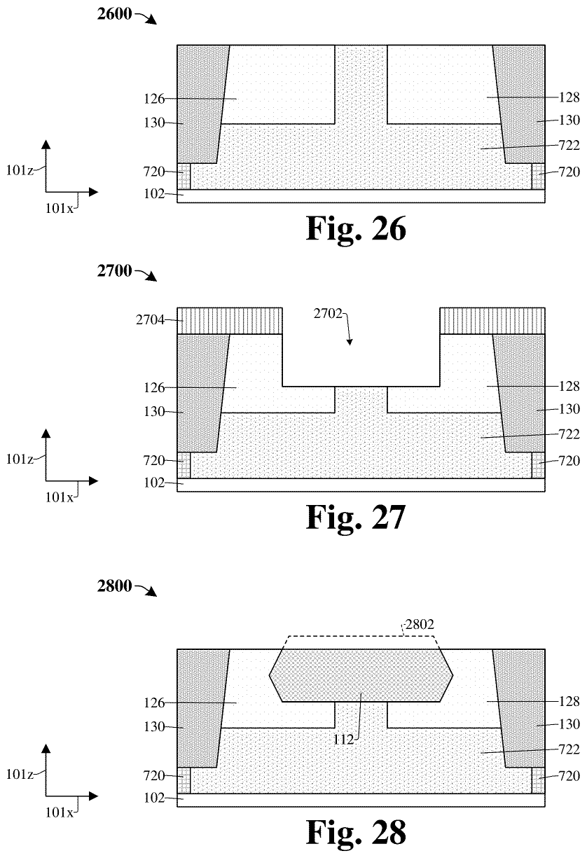

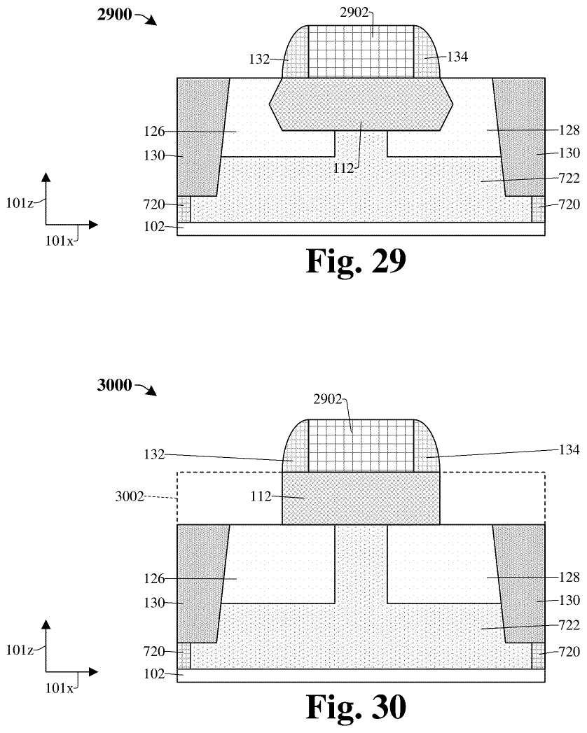

FIG. 13 illustrates a cross-sectional view 1300 and FIG. 14 illustrates cross-section view 1400 of some embodiments of the integrated chip of FIGS. 10-12 in which the gate electrode 110 includes a plurality of base metal layers and a plurality of work function metal layers. FIGS. 15-17 illustrate top views 1500-1700 of some embodiments of the integrated chip of FIG. 13 and FIG. 14. FIG. 18 illustrates a cross-sectional view 1800 of some embodiments of the integrated chip of FIGS. 16 and 17. In some embodiments, top view 1500 of FIG. 15 is taken across line I-I′ of FIG. 13 and line J-J′ of FIG. 14. In some embodiments, top view 1600 of FIG. 16 is taken across line K-K′ of FIG. 18. In some embodiments, top view 1700 of FIG. 17 is taken across line I-I′ of FIG. 13 and line J-J′ of FIG. 14. In some other embodiments, top view 1700 of FIG. 17 is taken across line K-K′ of FIG. 18.

In some embodiments, the gate electrode 110 includes the first base metal layer 1002 and a second base metal layer 1302 over and between sidewalls of the first base metal layer 1002. Further, the gate electrode 110 includes the first work function metal layer 1004 and a second work function metal layer 1304 over and between sidewalls of the first work function metal layer 1004. By including multiple work function metal layers and multiple base metal layers in the gate electrode 110, the threshold voltage of the transistor 101 can be further tuned.

The base metal layers 1002, 1302 comprise tungsten, aluminum, or some other suitable material. The work function metal layers 1004, 1304 comprise hafnium, zirconium, titanium, tantalum, ruthenium, palladium, platinum, cobalt, nickel, or some other suitable material.

In some embodiments (e.g., as illustrated in FIGS. 15 and 17), a first portion of the work function metal layers 1004, 1304 is laterally spaced from a second portion of the work function metal layers 1004, 1304, and the base metal layers 1002, 1302 laterally surround the first and second portions of the work function metal layers 1004, 1304 and extends between the first and second portions of the work function metal layers 1004, 1304. The portions of the work function metal layers 1004, 1304 are elongated along axis 101x. In some embodiments (e.g., as illustrated in FIG. 17), a third portion of the work function metal layers 1004, 1304 is spaced between the first and second portions. In some embodiments (e.g., as illustrated in FIG. 16), the work function metal layers 1004, 1304 extend continuously from a first edge of the active area of the transistor 101 to a second edge of the active area. By adjusting the position of the work function metal layers 1004, 1304 in the gate electrode 110, the threshold voltage of the transistor 101 can be further tuned.

In some embodiments, the widths of the portions of the work function metal layers 1004, 1304 (e.g., as measured along axis 101x) range from 0.01 micrometers to 1 micrometer, 0.1 micrometers to 0.2 micrometers, or some other suitable range. In some embodiments, the lengths of the portions of the work function metal layers 1004, 1304 (e.g., as measured along axis 101y) range from 0.5 micrometers to 10 micrometers, 1 micrometer to 8 micrometers, or some other suitable range.

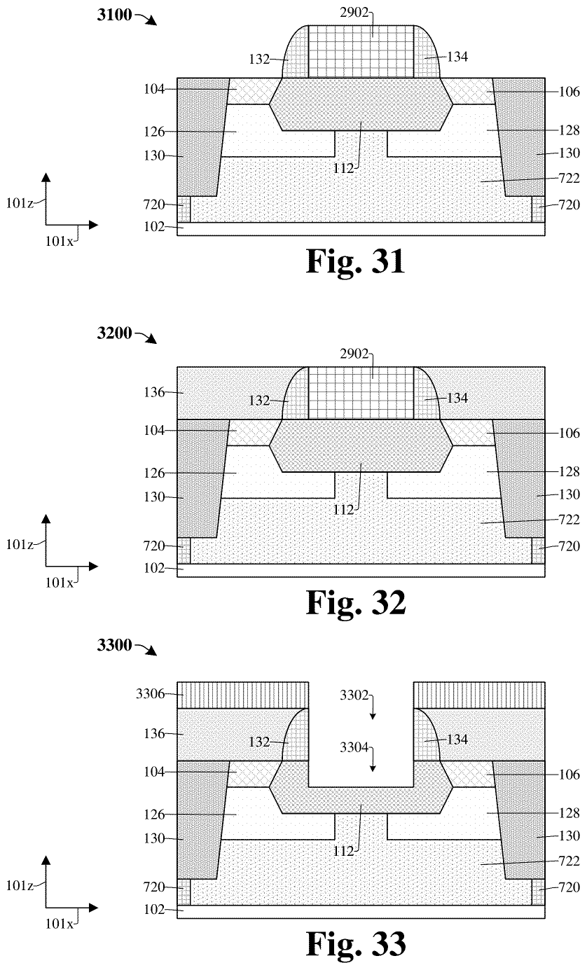

FIGS. 19-21 illustrate top views 1900-2100 of some other embodiments of the gate electrode 110 and the gate dielectric layer 112 of FIGS. 15-17.

In some embodiments (e.g., as illustrated in FIG. 19), the first work function metal layer 1004 of the gate electrode 110 extends laterally through the second base metal layer 1302 of the gate electrode 110 from a first sidewall of the first base metal layer 1002 of the gate electrode 110 to a second sidewall of the first base metal layer 1002. In some embodiments (e.g., as illustrated in FIG. 20), the second base metal layer 1302 of the gate electrode 110 laterally surrounds the first work function metal layer 1004 of the gate electrode 110. In some embodiments (e.g., as illustrated in FIG. 21), the first work function metal layer 1004 of the gate electrode 110 extends laterally through the second base metal layer 1302 of the gate electrode 110 and into the first base metal layer 1002 of the gate electrode 110.

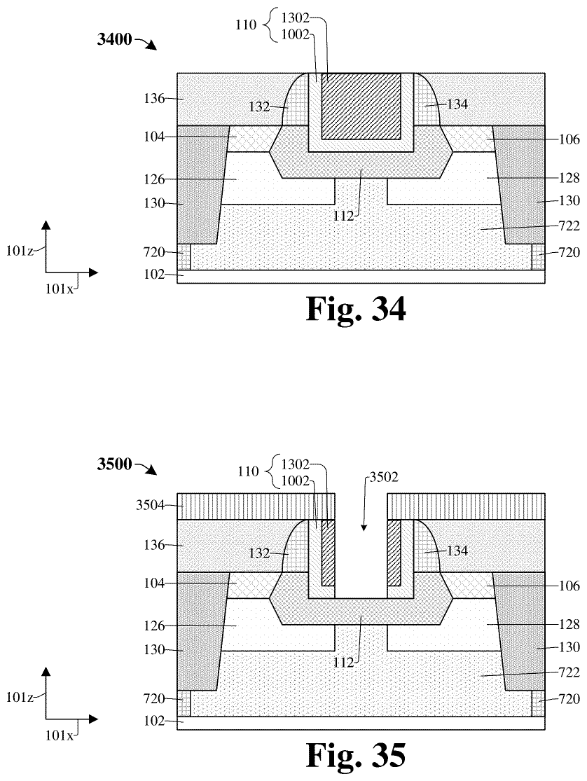

FIGS. 22-25 illustrate cross-sectional views 2200-2500 of some other embodiments of the integrated chip of FIG. 18.

In some embodiments (e.g., as illustrated in FIG. 22), both the gate dielectric layer 112 and the gate electrode 110 are below the top surface 102a of the semiconductor substrate 102 and above the top surface 102a of the semiconductor substrate 102. In some other embodiments (e.g., as illustrated in FIG. 23), the gate dielectric layer 112 is below the top surface 102a of the semiconductor substrate 102 and above the top surface 102a of the semiconductor substrate 102, and the bottom surface 110c of the gate electrode 110 is spaced over the top surface 102a of the semiconductor substrate 102. In some other embodiments (e.g., as illustrated in FIG. 24 and FIG. 25), the gate dielectric layer 112 is on the top surface 102a of the semiconductor substrate 102 and the bottom surface 110c of the gate electrode 110 is spaced over the top surface 102a of the semiconductor substrate 102. In some embodiments (e.g., as illustrated in FIG. 25), the gate dielectric layer 112 extends laterally along the top surface 102a of the semiconductor substrate 102 beyond the sidewall spacers 132, 134.

By adjusting the position of the gate electrode 110 and the gate dielectric layer 112, the position of the channel region 108 can be tuned and thus the performance and reliability of the transistor 101 can be tuned.

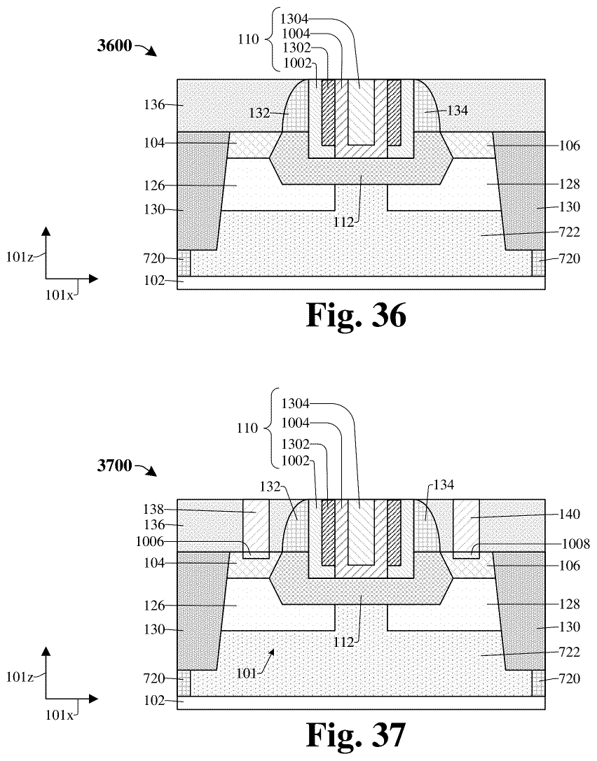

FIGS. 26-37 illustrate cross-sectional views 2600-3700 of some embodiments of a method for forming an integrated chip including a transistor 101 along a semiconductor substrate 102. Although FIGS. 26-37 are described in relation to a method, it will be appreciated that the structures disclosed in FIGS. 26-37 are not limited to such a method, but instead may stand alone as structures independent of the method.

As shown in cross-sectional view 2600 of FIG. 26, an STI structure 130 is formed along a semiconductor substrate 102. The STI structure 130 surrounds a portion of the semiconductor substrate 102. In some embodiments, forming the STI structure 130 comprises etching the semiconductor substrate 102 to form a trench in the semiconductor substrate 102, depositing a dielectric in the trench, and performing a planarization process (e.g., a chemical mechanical planarization process, an etching planarization process, or some other suitable planarization process) on the dielectric and the semiconductor substrate 102. In some embodiments, the STI structure 130 comprises silicon oxide or some other suitable material.

Further, as shown in cross-sectional view 2600 of FIG. 26, a heavily doped well region 720 is formed in the semiconductor substrate 102, a lightly doped well region 722 is formed in the heavily doped well region 720, and a pair of lightly doped source/drain regions 126, 128 are formed in the lightly doped well region 722. In some embodiments, the semiconductor substrate 102 comprises silicon or some other suitable semiconductor. In some embodiments, the heavily doped well region 720 has a first doping type, the lightly doped well regions 722, 724 have the first doping type, and the lightly doped source/drain regions 126, 128 have a second doping type, different than the first doping type. In some embodiments, the heavily doped well region 720 is formed by a first ion implantation process or some other suitable process, the lightly doped well region 722 is formed by a second ion implantation process or some other suitable process, and the pair of lightly doped source/drain regions 126, 128 are formed by a third ion implantation process or some other suitable process.

FIGS. 27-29 illustrate cross-sectional views 2700-2900 of some embodiments of a method for forming a gate dielectric layer 112 and a dummy gate structure 2902 along the semiconductor substrate 102.

As shown in cross-sectional view 2700 of FIG. 27, the semiconductor substrate 102 is etched to form a trench 2702 in the semiconductor substrate 102 between the lightly doped source/drain regions 126, 128. In some embodiments, a masking layer 2704 is formed over the semiconductor substrate 102 and the etching is performed according to the masking layer 2704. In some embodiments, the etching comprises a dry etching process such as a plasma etching process, a reactive ion etching process, an ion beam etching process, or some other suitable process. In some embodiments, the trench 2702 extends into the semiconductor substrate 102 to a depth that is less than the depth of the lightly doped source/drain regions 126, 128.

As shown in cross-sectional view 2800 of FIG. 28, a gate dielectric layer 112 is deposited in the trench 2702. In some embodiments, the gate dielectric layer 112 comprises silicon oxide, hafnium oxide, aluminum oxide, or some other suitable material and is deposited by an epitaxial growth process, a chemical vapor deposition (CVD) process, a physical vapor deposition (PVD) process, an atomic layer deposition (ALD) process, or some other suitable process. In some embodiments, a planarization process is performed on the gate dielectric layer 112 and the semiconductor substrate 102 after the gate dielectric layer 112 is deposited over the semiconductor substrate 102 so that a top surface of the gate dielectric layer 112 and a top surface of the semiconductor substrate 102 are approximately coplanar. In some other embodiments, the gate dielectric layer 112 extends above the top surface of the semiconductor substrate 102 (e.g., as illustrated by dashed line 2802).

As shown in cross-sectional view 2900 of FIG. 29, a dummy gate structure 2902 is formed over the gate dielectric layer 112 and a pair of sidewall spacers 132, 134 are formed along sidewalls of the dummy gate structure 2902. In some embodiments, the dummy gate structure 2902 comprises polysilicon or some other suitable material and is deposited by a CVD process, a PVD process, an ALD process, or some other suitable process. In some embodiments, the sidewall spacers 132, 134 comprise silicon oxide, silicon nitride, or some other suitable material and are deposited by a CVD process, a PVD process, an ALD process, or some other suitable process.

FIG. 30 illustrates a cross-sectional view 3000 of some other embodiments of a method for forming the gate dielectric layer 112 and the dummy gate structure 2902 along the semiconductor substrate 102.

As shown in cross-sectional view 3000 of FIG. 30, the etching of the semiconductor substrate 102 to form the trench 2702 is omitted. Rather, the gate dielectric layer 112 is deposited on the top surface of the semiconductor substrate 102. Further, the dummy gate structure 2902 is formed on the gate dielectric layer 112 and the sidewall spacers 132, 134 are formed along the sidewalls of the dummy gate structure 2902. In some embodiments, the gate dielectric layer 112 is etched to delimit the gate dielectric layer 112. In some other embodiments, the gate dielectric layer 112 extends laterally along the semiconductor substrate 102 beyond the sidewall spacers 132, 134, as illustrated by dashed line 3002.

As shown in cross-sectional view 3100 of FIG. 31, a pair of source/drain regions 104, 106 are formed along the semiconductor substrate 102 on opposite sides of the dummy gate structure 2902 and in the lightly doped source/drain regions 126, 128, respectively. In some embodiments, the source/drain regions 104, 106 are formed by an ion implantation process or some other suitable process. The source/drain regions 104, 106 have the second doping type. A doping concentration of the source/drain regions 104, 106 is greater than the doping concentration of the lightly doped source/drain regions 126, 128.

As shown in cross-sectional view 3200 of FIG. 32, one or more dielectric layers of a dielectric structure 136 are formed over the semiconductor substrate 102 and the dummy gate structure 2902. In addition, a planarization process is performed on the dielectric layer(s) of the dielectric structure 136 to remove the dielectric layer(s) from over the dummy gate structure 2902. In some embodiments, the dielectric layer(s) of the dielectric structure 136 comprises silicon oxide, silicon nitride, or some other suitable material and is deposited by a CVD process, a PVD process, an ALD process, or some other suitable process. In some embodiments, the planarization process comprises a chemical mechanical planarization or some other suitable process.

As shown in cross-sectional view 3300 of FIG. 33, the dummy gate structure 2902 is removed from between the sidewall spacers 132, 134 and from over the gate dielectric layer 112, thereby leaving an opening 3302 in place of the dummy gate structure 2902. Further, a portion of the gate dielectric layer 112 is removed to form a trench 3304 in the gate dielectric layer 112. In some embodiments, removing the dummy gate structure 2902 and the portion of the gate dielectric layer 112 comprises etching the dummy gate structure 2902 and the gate dielectric layer 112 according to a masking layer 3306 with a dry etching process or some other suitable process. In some embodiments, the gate dielectric layer 112 laterally surrounds trench 3304 in a closed path (e.g., as illustrated in FIG. 2. In some other embodiments, the gate dielectric layer 112 is on opposite sides of trench 3304 (e.g., as illustrated in FIG. 5).

As shown in cross-sectional view 3400 of FIG. 34, a gate electrode 110 is formed in opening 3302 and trench 3304 to replace the dummy gate structure 2902 and fill trench 3304. The gate electrode 110 is formed by depositing a first base metal layer 1002 in the opening 3302 and trench 3304. In some embodiments, the first base metal layer 1002 fills opening 3302 and trench 3304. In some other embodiments, one or more additional base metal layers are deposited over the first base metal layer 1002 in opening 3302 and trench 3304. For example, in some embodiments, a second base metal layer 1302 is deposited over the first base metal layer 1002 in opening 3302 and trench 3304. In some embodiments, the first base metal layer 1002 comprises a first metal and is deposited by a first deposition process, and the second base metal layer 1302 comprises a second metal and is deposited by a second deposition process. In some embodiments, the first metal and/or the second metal comprise tungsten, aluminum, or some other suitable material. In some embodiments, the first deposition process and/or the second deposition process comprise any of a CVD process, a PVD process, an ALD process, or some other suitable process. In some embodiments, a planarization process is performed on the base metal layers after deposition.

As shown in cross-sectional view 3500 of FIG. 35, the base metal layer(s) of the gate electrode 110 are etched to form trench(s) 3502 in the base metal layer(s). For example, in some embodiments, the second base metal layer 1302 and the first base metal layer 1002 are etched to form a trench 3502 in the second base metal layer 1302 and the first base metal layer 1002. In some embodiments, the second base metal layer 1302 and the first base metal layer 1002 are etched according to a masking layer 3504 with a dry etching process or some other suitable etching process. In some embodiments, the etching uncovers an upper surface of the gate dielectric layer 112.

As shown in cross-sectional view 3600 of FIG. 36, the gate electrode 110 is further formed by depositing a first work function metal layer 1004 in trench 3502. In some embodiments, the first work function metal layer 1004 fills trench 3502. In some other embodiments, one or more additional work function metal layers are deposited over the first work function metal layer 1004 in trench 3502. For example, in some embodiments, a second work function metal layer 1304 is deposited over the first work function metal layer 1004 in trench 3502. In some embodiments, the first work function metal layer 1004 comprises a third metal and is deposited by a third deposition process, and the second work function metal layer 1304 comprises a fourth metal and is deposited by a fourth deposition process. In some embodiments, the third metal and/or the fourth metal comprise any of hafnium, zirconium, titanium, tantalum, ruthenium, palladium, platinum, cobalt, nickel, or some other suitable material. In some embodiments, the third deposition process and/or the fourth deposition process comprise any of a CVD process, a PVD process, an ALD process, or some other suitable process. In some embodiments, a planarization process is performed on the work function metal layers after deposition.

As shown in cross-sectional view 3700 of FIG. 37, contacts are formed over the semiconductor substrate 102 and contacting the transistor. For example, a first contact 138 is formed on the first source/drain region 104, a second contact 140 is formed on the second source/drain region 106, and a third contact (not shown) is formed on the gate electrode 110. In some embodiments, the contacts are formed by etching the dielectric structure 136 to uncover portions of the first source/drain region 104, the second source/drain region 106, and the gate electrode 110, and by subsequently depositing (e.g., with a CVD process, a PVD process, an ALD process, or some other suitable process) a metal (e.g., tungsten, aluminum, or some other suitable material) over the etched dielectric structure 136. In some embodiments, silicide layers are formed along bottoms of the contacts. For example, in some embodiments, a first silicide layer 1006 is formed along a bottom of the first contact 138 and a second silicide layer 1008 is formed along a bottom of the second contact 140.

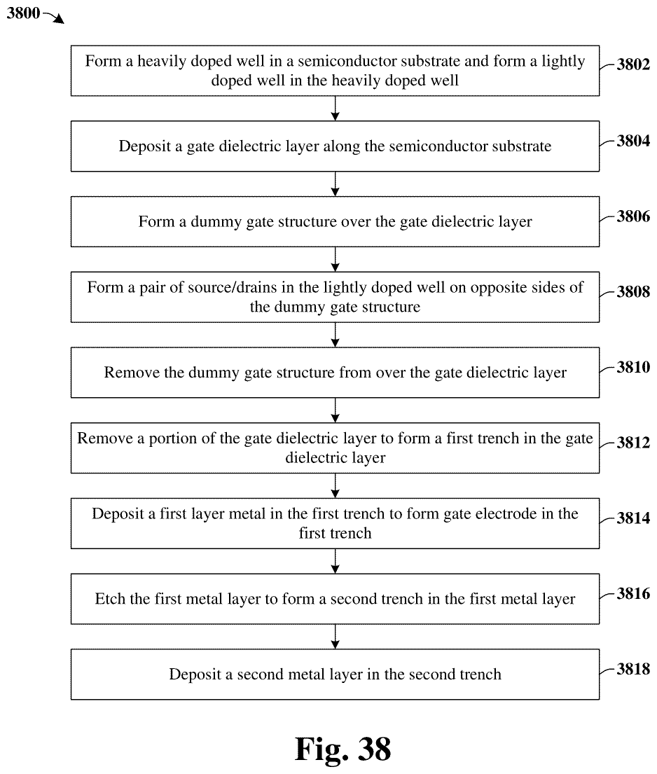

FIG. 38 illustrates a flow diagram of some embodiments of a method 3800 for forming an integrated chip including a transistor along a semiconductor substrate. While method 3800 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At block 3802, form a heavily doped well in a semiconductor substrate and form a lightly doped well in the heavily doped well. In some embodiments, a pair of lightly doped source/drain regions are formed in the lightly doped well. FIG. 26 illustrates a cross-sectional view 2600 of some embodiments corresponding to block 3802.

At block 3804, deposit a gate dielectric layer along the semiconductor substrate. In some embodiments, a trench is formed in the semiconductor substrate and the gate dielectric layer is deposited in the trench. In some other embodiments, the gate dielectric layer is deposited on a top surface of the semiconductor substrate. FIG. 28 illustrates a cross-sectional view 2800 of some embodiments corresponding to block 3804. FIG. 30 illustrates a cross-sectional view 3000 of some other embodiments corresponding to block 3804.

At block 3806, form a dummy gate structure over the gate dielectric layer. FIG. 29 illustrates a cross-sectional view 2900 of some embodiments corresponding to block 3806. FIG. 30 illustrates a cross-sectional view 3000 of some other embodiments corresponding to block 3806.

At block 3808, form a pair of source/drains in the lightly doped well on opposite sides of the dummy gate structure. FIG. 31 illustrates a cross-sectional view 3100 of some embodiments corresponding to block 3808.

At block 3810, remove the dummy gate structure from over the gate dielectric layer. FIG. 33 illustrates a cross-sectional view 3300 of some embodiments corresponding to block 3810.

At block 3812, remove a portion of the gate dielectric layer to form a first trench in the gate dielectric layer. FIG. 33 illustrates a cross-sectional view 3300 of some embodiments corresponding to block 3812.

At block 3814, deposit a first layer metal in the first trench to form gate electrode in the first trench. FIG. 34 illustrates a cross-sectional view 3400 of some embodiments corresponding to block 3814.

At block 3816, etch the first metal layer to form a second trench in the first metal layer. FIG. 35 illustrates a cross-sectional view 3500 of some embodiments corresponding to block 3816.

At block 3818, deposit a second metal layer in the second trench. The second metal has a different work function type than the source/drains. FIG. 36 illustrates a cross-sectional view 3600 of some embodiments corresponding to block 3818.

Accordingly, in some embodiments, the present disclosure relates to an integrated chip including a semiconductor substrate, a first source/drain region, a second source/drain region, a gate electrode, and a gate dielectric layer. The first source/drain region and the second source/drain region are along the semiconductor substrate. A channel region extends along the semiconductor substrate from the first source/drain region to the second source/drain region. The gate electrode is between the first source/drain region and the second source/drain region. The gate electrode has a first outer sidewall, a second outer sidewall, and a bottom surface extending from the first outer sidewall to the second outer sidewall. The gate dielectric layer is between the gate electrode and the channel region. A lateral portion of the gate dielectric layer extends laterally along the bottom surface of the gate electrode. A first vertical portion of the gate dielectric layer extends upward from the lateral portion along the first outer sidewall of the gate electrode. A second vertical portion of the gate dielectric layer extends upward from the lateral portion along the second outer sidewall of the gate electrode.

In other embodiments, the present disclosure relates to an integrated chip including a semiconductor substrate, a first source/drain region, a second source/drain region, a gate dielectric layer, and a gate electrode. The first source/drain region and the second source/drain region are along the semiconductor substrate. A channel region extends along the semiconductor substrate from the first source/drain region to the second source/drain region. The gate dielectric layer is over the channel region and between the first source/drain region and the second source/drain region. The gate dielectric layer has a first inner sidewall, a second inner sidewall, and a first upper surface extending from a bottom of the first inner sidewall to a bottom of the second inner sidewall. The gate electrode is between the first source/drain region and the second source/drain region. The gate electrode is over the first upper surface of the gate dielectric layer and between the first inner sidewall and the second inner sidewall of the gate dielectric layer. A horizontal line intersects the gate electrode, the first inner sidewall of the gate dielectric layer, and the second inner sidewall of the gate dielectric layer.

In yet other embodiments, the present disclosure relates to a method for forming an integrated chip. The method includes depositing a gate dielectric layer along a semiconductor substrate. The method includes forming a dummy gate structure over the gate dielectric layer. The method includes forming a first source/drain region and a second source/drain region along the semiconductor substrate on opposite sides of the dummy gate structure. The method includes etching the dummy gate structure to remove the dummy gate structure from over the gate dielectric layer. The method includes etching the gate dielectric layer to remove a portion of the gate dielectric layer to form a first trench in the gate dielectric layer. The method includes forming a gate electrode over the gate dielectric layer and in the first trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip comprising:
a semiconductor substrate;
a first source/drain region and a second source/drain region along the semiconductor substrate, wherein a channel region extends along the semiconductor substrate from the first source/drain region to the second source/drain region;
a gate electrode between the first source/drain region and the second source/drain region, the gate electrode having a first outer sidewall, a second outer sidewall, and a bottom surface extending from the first outer sidewall to the second outer sidewall; and
a gate dielectric layer between the gate electrode and the channel region, a lateral portion of the gate dielectric layer extending laterally along the bottom surface of the gate electrode, a first vertical portion of the gate dielectric layer extending upward from the lateral portion along the first outer sidewall of the gate electrode, and a second vertical portion of the gate dielectric layer extending upward from the lateral portion along the second outer sidewall of the gate electrode.

2. The integrated chip of claim 1, wherein a top of the first vertical portion and a top of the second vertical portion are above the bottom surface of the gate electrode and below a top surface of the gate electrode.

3. The integrated chip of claim 2, further comprising:
a first spacer extending along the first outer sidewall of the gate electrode over the first vertical portion of the gate dielectric layer; and
a second spacer extending along the second outer sidewall of the gate electrode over the second vertical portion of the gate dielectric layer.

4. The integrated chip of claim 1, wherein a distance between a top of the first vertical portion and a bottom of the lateral portion and a distance between a top of the second vertical portion and the bottom of the lateral portion are greater than a distance between a top of the lateral portion and the bottom of the lateral portion.

5. The integrated chip of claim 1, wherein the lateral portion is partially formed by a bottom surface of the gate dielectric layer and a first upper surface of the gate dielectric layer that extends along the bottom surface of the gate electrode, wherein the first vertical portion is partially formed by the bottom surface of the gate dielectric layer, a first inner sidewall of the gate dielectric layer that extends upward from the first upper surface of the gate dielectric layer along the first outer sidewall of the gate electrode, a first outer sidewall of the gate dielectric layer that extends upward from the bottom surface of the gate dielectric layer, and a second upper surface of the gate dielectric layer that extends from the first inner sidewall of the gate dielectric layer to the first outer sidewall of the gate dielectric layer, and wherein the second vertical portion is partially formed by the bottom surface of the gate dielectric layer, a second inner sidewall of the gate dielectric layer that extends upward from the first upper surface of the gate dielectric layer along the second outer sidewall of the gate electrode, a second outer sidewall of the gate dielectric layer that extends upward from the bottom surface of the gate dielectric layer, and a third upper surface of the gate dielectric layer that extends from the second inner sidewall of the gate dielectric layer to the second outer sidewall of the gate dielectric layer.

6. The integrated chip of claim 1, the gate electrode comprising:
a first metal layer comprising a first metal on the lateral portion of the gate dielectric layer; and
a second metal layer comprising a second metal, different than the first metal, on the lateral portion of the gate dielectric layer and between a pair of sidewalls of the first metal layer,
wherein the first source/drain region and the second source/drain region have work functions of a first type, and wherein the second metal has a work function of a second type different than the first type.

7. The integrated chip of claim 6, the gate electrode further comprising:
a third metal layer comprising a third metal, different than the second metal, over the first metal layer and between the pair of sidewalls of the first metal layer; and
a fourth metal layer comprising a fourth metal, different than the first metal and the third metal, on the second metal layer and between a pair of sidewalls of the second metal layer, wherein the fourth metal has a work function of the second type.

8. The integrated chip of claim 6, wherein a first portion of the second metal layer is laterally spaced from a second portion of the second metal layer, and wherein the first metal layer laterally surrounds the first and second portions of the second metal layer and extends between the first and second portions of the second metal layer.

9. The integrated chip of claim 6, further comprising:
a first well region in the semiconductor substrate, the first well region having a first doping concentration; and
a second well region in the first well region, the second well region having a second doping concentration less than the first doping concentration, wherein the first source/drain region and the second source/drain region are in the second well region.

10. The integrated chip of claim 9, further comprising:
a third well region in the first well region and laterally spaced from the second well region, the third well region having a third doping concentration less than the first doping concentration, wherein the first well region laterally surrounds the second well region and the third well region, and wherein the first well region extends between the second well region and the third well region.

11. An integrated chip comprising:
a semiconductor substrate;
a first source/drain region and a second source/drain region along the semiconductor substrate, wherein a channel region extends along the semiconductor substrate from the first source/drain region to the second source/drain region;
a gate dielectric layer over the channel region and between the first source/drain region and the second source/drain region, the gate dielectric layer having a first inner sidewall, a second inner sidewall, and a first upper surface extending from a bottom of the first inner sidewall to a bottom of the second inner sidewall; and
a gate electrode between the first source/drain region and the second source/drain region, wherein the gate electrode is over the first upper surface of the gate dielectric layer and between the first inner sidewall and the second inner sidewall of the gate dielectric layer,
wherein a horizontal line intersects the gate electrode, the first inner sidewall of the gate dielectric layer, and the second inner sidewall of the gate dielectric layer.

12. The integrated chip of claim 11, wherein a thickness of the gate dielectric layer from a top of the first inner sidewall of the gate dielectric layer to a bottom surface of the gate dielectric layer and a thickness of the gate dielectric layer from a top of the second inner sidewall of the gate dielectric layer to the bottom surface of the gate dielectric layer are greater than a thickness of the gate dielectric layer from the first upper surface of the gate dielectric layer to the bottom surface of the gate dielectric layer.

13. The integrated chip of claim 11, wherein a bottom surface of the gate electrode and the first upper surface of the gate dielectric layer are below a top surface of the semiconductor substrate, a top of the first source/drain region, and a top of the second source/drain region, wherein the first inner sidewall of the gate dielectric layer is between a first outer sidewall of the gate electrode and the first source/drain region, and wherein the second inner sidewall of the gate dielectric layer is between a second outer sidewall of the gate electrode and the second source/drain region.

14. The integrated chip of claim 13, wherein the first inner sidewall of the gate dielectric layer extends from the first upper surface to a second upper surface of the gate dielectric layer, wherein the second inner sidewall of the gate dielectric layer extends from the first upper surface to a third upper surface of the gate dielectric layer, and wherein the second upper surface and the third upper surface of the gate dielectric layer are above the top surface of the semiconductor substrate, the top of the first source/drain region, and the top of the second source/drain region.

15. The integrated chip of claim 11, wherein a bottom surface of the gate electrode and the first upper surface of the gate dielectric layer are above a top surface of the semiconductor substrate, a top of the first source/drain region, and a top of the second source/drain region, and wherein a bottom surface of the gate dielectric layer is below the top surface of the semiconductor substrate, the top of the first source/drain region, and the top of the second source/drain region.

16. The integrated chip of claim 11, wherein a bottom surface of the gate electrode and the first upper surface of the gate dielectric layer are above a top surface of the semiconductor substrate, a top of the first source/drain region, and a top of the second source/drain region, and wherein a bottom surface of the gate dielectric layer is on the top surface of the semiconductor substrate.

17. A method for forming an integrated chip, the method comprising:
depositing a gate dielectric layer along a semiconductor substrate;
forming a dummy gate structure over the gate dielectric layer;
forming a first source/drain region and a second source/drain region along the semiconductor substrate on opposite sides of the dummy gate structure;
etching the dummy gate structure to remove the dummy gate structure from over the gate dielectric layer;
etching the gate dielectric layer to remove a portion of the gate dielectric layer to form a first trench in the gate dielectric layer; and
forming a gate electrode over the gate dielectric layer and in the first trench.

18. The method of claim 17, further comprising:
etching the semiconductor substrate to form a second trench in the semiconductor substrate,
wherein the gate dielectric layer is deposited in the second trench.

19. The method of claim 17, wherein forming the gate electrode comprises:
depositing a first conductive layer comprising a first conductor in the first trench;
etching the first conductive layer to form a second trench in the first conductive layer; and
depositing a second conductive layer comprising a second conductor, different than the first conductor, in the second trench,
wherein the first source/drain region and the second source/drain region have work functions of a first type, and wherein the second conductor has a work function of a second type different than the first type.

20. The method of claim 17, further comprising:
forming a first well region in the semiconductor substrate, the first well region having a first doping concentration; and
forming a second well region in the first well region, the second well region having a second doping concentration less than the first doping concentration, wherein the first source/drain region and the second source/drain region are formed in the second well region.
